(19) United States
(12) Patent Application Publication
(10) Pub. No.: US 2025/0311579 A1
(43) Pub. Date: Oct. 2, 2025

(54) DISPLAY APPARATUS

(71) Applicant: Samsung Display Co., Ltd., Yongin-Si (KR)

(72) Inventors: Gina Yoo, Yongin-si (KR); Hyomin Kim, Yongin-si (KR); Sijin Sung, Yongin-si (KR)

(21) Appl. No.: 19/026,760

(22) Filed: Jan. 17, 2025

(30) Foreign Application Priority Data
Mar. 27, 2024 (KR) 10-2024-0042005

(51) Int. Cl. H10K 59/35; H10K 59/126

(52) U.S. Cl. CPC H10K 59/352; H10K 59/126; H10K 59/353

(57) ABSTRACT

A display apparatus according to a present disclosure includes a substrate, a pixel-defining film, a first metal pattern, and a light blocking layer, wherein a ratio of a length of the first emission area in a first direction, a length of the second emission area in the first direction, and a length of the third emission area in the first direction is same as a ratio of each of lengths from an end of the light blocking layer extending in a second direction and surrounding the first emission area, the second emission area, and the third emission area to an end of the first metal pattern adjacent thereto.

### CROSS-REFERENCE TO RELATED APPLICATION

This application is based on and claims priority under 35 U.S.C. § 119 to Korean Patent Application No. 10-2024-0042005, filed on Mar. 27, 2024, in the Korean Intellectual Property Office, the disclosure of which is incorporated by reference herein in its entirety.

### BACKGROUND

### 1. Field

The present disclosure relates to a display apparatus.

### 2. Description of the Related Art

A display apparatus visually displays image corresponding to data. A display apparatus may provide an image by using light-emitting diodes. A display apparatus has been used for various purposes, and various designs have been attempted to improve the quality of the display apparatus.

### SUMMARY

The present disclosure provides one or more embodiments which include a display apparatus.

Additional aspects will be set forth in the description which follows and will be apparent from the description.

According to an embodiment, a display apparatus includes a substrate including a first emission area, a second emission area, and a third emission area, a pixel-defining film disposed on the substrate and including an opening, a first metal pattern disposed on the pixel-defining film, and a light blocking layer covering the first metal pattern and arranged to surround at least a part of each of the first, second, and third emission areas, wherein a ratio of a length of the first emission area in a first direction, a length of the second emission area in the first direction, and a length of the third emission area in the first direction is same as a ratio of a length from an end of the light blocking layer extending in a second direction intersecting the first direction and surrounding the first emission area to an end of the adjacent first metal pattern, a length from an end of the light blocking layer extending in the second direction and surrounding the second emission area to an end of the adjacent first metal pattern, and a length from an end of the light blocking layer extending in the second direction and surrounding the third emission area to an end of the adjacent first metal pattern.

The first metal pattern may be arranged to surround at least a part of each of the first, second, and third emission areas.

The first emission area, the second emission area, and the third emission area may be each defined by the opening of the pixel-defining film.

The display apparatus may further include a first organic light-emitting diode, a second organic light-emitting diode, and a third organic light-emitting diode, wherein each of the first organic light-emitting diode, the second organic light-emitting diode, and the third organic light-emitting diode includes a pixel electrode disposed to correspond to the opening of the pixel-defining film, an emission layer disposed on the pixel electrode, and a counter electrode disposed on the emission layer.

The first organic light-emitting diode may be configured to emit red light, the second organic light-emitting diode may be configured to emit green light, and the third organic light-emitting diode may be configured to emit blue light.

The first organic light-emitting diode may be disposed to correspond to the first emission area, the second organic light-emitting diode may be disposed to correspond to the second emission area, and the third organic light-emitting diode may be disposed to correspond to the third emission area.

The display apparatus may further include a second metal pattern disposed under the first metal pattern.

The display apparatus may further include an insulating layer disposed between the first metal pattern and the second metal pattern.

The first metal pattern and the second metal pattern may be electrically connected to each other through a contact hole.

According to an embodiment, a display apparatus includes a substrate including a first emission area, a second emission area, and a third emission area, a pixel-defining film disposed on the substrate and including an opening, a first metal pattern disposed on the pixel-defining film, and a light blocking layer covering the first metal pattern and arranged to surround at least a part of each of the first, second, and third emission areas, wherein the light blocking layer extending in a first direction and surrounding the second emission area includes a first edge protruding to an edge of the second emission area and a second edge extending in a first direction and disposed farther from the edge of the second emission area than the first edge, and wherein a ratio of a length of the first emission area in a second direction intersecting the first direction, a length of the second emission area in the second direction, and a length of the third emission area in the second direction is same as a ratio of a length from an end of the light blocking layer extending in the first direction and surrounding the first emission area to an end of the adjacent first metal pattern, a length from an end of the first edge of the light blocking layer surrounding the second edge area to an end of the adjacent first metal pattern, and a length from an end of the light blocking layer extending in the first direction and surrounding the third emission area to an end of the adjacent first metal pattern.

The length from the end of the first edge of the light blocking layer surrounding the second emission area to the end of the adjacent first metal pattern and a length from an end of the second edge of the light blocking layer to an end of the adjacent first metal pattern may be different from each other.

The light blocking layer extending in the first direction and surrounding the third emission area may include a third edge protruding to an edge of the third emission area and a fourth edge extending in the first direction and disposed farther from the edge of the third emission area than the third edge.

A length from an end of the third edge of the light blocking layer surrounding the third emission area to the adjacent first metal pattern and a length from an end of the fourth edge of the light blocking layer to the adjacent first metal pattern may be different from each other.

A ratio of the length of the first emission area in the second direction, the length of the second emission area in the second direction, and the length of the third emission area in the second direction may be same as a ratio of the length from the end of the light blocking layer extending in the first direction and surrounding the first emission area to the end of the adjacent first metal pattern, the length from the end of the first edge of the light blocking layer surrounding the second emission area to the end of the adjacent first metal pattern, and the length from the end of the third edge of the light blocking layer surrounding the third emission area to an end of the adjacent first metal pattern.

The first edge of the light blocking layer surrounding the second emission area may include a 1-1 edge and a 1-2 edge.

A length from an end of the 1-1 edge of the light blocking layer surrounding the second emission area to the adjacent first metal pattern and a length from an end of the 1-2 edge of the light blocking layer to the adjacent first metal pattern may be different from each other.

A ratio of the length of the first emission area in the second direction, the length of the second emission area in the second direction, and the length of the third emission area in the second direction may be same as a ratio of the length from the end of the light blocking layer extending in the first direction and surrounding the first emission area to the end of the adjacent first metal pattern, the length from the end of the 1-1 edge of the light blocking layer surrounding the second emission area to an end of the adjacent first metal pattern, and the length from the end of the light blocking layer extending in the first direction and surrounding the third emission area to the end of the adjacent first metal pattern.

The light blocking layer extending in the first direction and surrounding the third emission area may include a third edge protruding to an edge of the third emission area and a fourth edge extending in the first direction and disposed farther from the edge of the third emission area than the third edge.

A length from an end of the third edge of the light blocking layer surrounding the third emission area to the adjacent first metal pattern and a length from an end of the fourth edge of the light blocking layer to the adjacent first metal pattern may be different from each other.

A ratio of the length of the first emission area in the second direction, the length of the second emission area in the second direction, and the length of the third emission area in the second direction may be same as a ratio of the length from the end of the light blocking layer extending in the first direction and surrounding the first emission area to the end of the adjacent first metal pattern, the length from the end of the 1-1 edge of the light blocking layer surrounding the second emission area to an end of the adjacent first metal pattern, and the length from the end of the third edge of the light blocking layer surrounding the third emission area to an end of the adjacent first metal pattern.

### BRIEF DESCRIPTION OF THE DRAWINGS

The above and other aspects, features, and advantages of the present disclosure will become more apparent by reference to the following description taken in conjunction with the accompanying drawings.

FIGS. 1 and 2 are perspective views schematically illustrating a display apparatus, according to an embodiment.

FIG. 3 is an equivalent circuit diagram schematically illustrating a sub-pixel circuit provided in a display apparatus, according to an embodiment.

FIG. 4 is a plan view schematically illustrating a display apparatus, according to an embodiment.

FIG. 5 is a schematic cross-sectional view taken along a line I-I′ of the display apparatus of FIG. 4.

FIGS. 6A and 6B are plan views schematically illustrating a display apparatus, according to an embodiment.

FIGS. 7A and 7B are plan views schematically illustrating a display apparatus, according to an embodiment.

### DETAILED DESCRIPTION

Hereinafter, specific embodiments of the present disclosure are explained in detail with reference to the accompanying drawings. Like numerals refer to like elements throughout the present disclosure. In this regard, embodiments of the present disclosure may have different forms and should not be construed as being limited to the descriptions set forth herein. Accordingly, the embodiments are merely described below, by referring to the drawings, to explain aspects of the present disclosure. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As the present disclosure allows for various changes and numerous embodiments, specific embodiments will be illustrated in the drawings and described in the detailed description. The effects and features of the present disclosure, as well as the methods for achieving them will become clear with reference to the detailed embodiments described below provided with reference to the drawings. However, it should be noted that the present disclosure is not limited to the following embodiments and may be implemented in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including,” and “having,” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the present disclosure is not limited thereto.

When a certain embodiment may be implemented differently, a specific process order may be different from the described order. For example, two consecutively described processes may be performed substantially at the same time or may be performed in an order opposite to the described order.

It will be understood that when a layer, a region, or a component is referred to as being “connected” to another layer, region, or component, it may be “directly connected” to the other layer, region, or component or may be “indirectly connected” to the other layer, region, or component with other layers, regions, or components interposed therebetween. For example, when a layer, a region, or a component is referred to as being “electrically connected,” it may be directly electrically connected, or may be indirectly electrically connected with intervening layers, regions, or components therebetween.

The x-axis, the y-axis and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

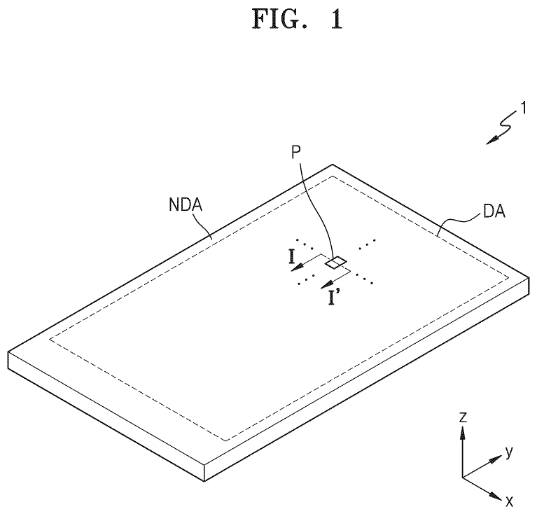

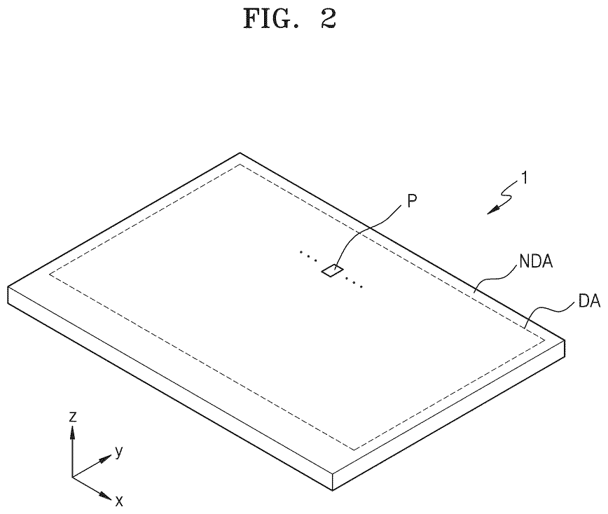

FIGS. 1 and 2 are perspective views schematically illustrating a display apparatus, according to an embodiment.

Referring to FIGS. 1 and 2, a display apparatus 1 may include a display area DA and a non-display area NDA located outside the display area DA. The display area DA may display an image through sub-pixels P disposed in the display area DA. The non-display area NDA, which is located outside the display area DA and does not display an image, may entirely surround the display area DA. A driver or the like for applying an electrical signal or power to the display area DA may be located in the non-display area NDA. A pad to which an electronic device or a printed circuit board may be electrically connected may be located in the non-display area NDA.

Although the display area DA has a polygonal shape (e.g., a quadrangular shape) in which a length in an x direction is less than a length in a y direction in FIG. 1, in an embodiment shown in FIG. 2, the display apparatus 1 may have a polygonal shape (e.g., a quadrangular shape) in which a length in the y direction is less than a length in the x direction. Although the display area DA has a substantially quadrangular shape in FIGS. 1 and 2, the disclosure is not limited thereto. In an, the display area DA may have any of various shapes such as an N-gon shape (where N is a natural number of 3 or more), a circular shape, or an elliptical shape. Although the display area DA has a shape with corners where straight lines meet each other in FIGS. 1 and 2, in an embodiment, the display area DA may have a polygonal shape with round corners.

Although it is considered for convenience of explanation that the display apparatus 1 is an electronic device such as a smartphone, the display apparatus 1 according to the present disclosure is not limited thereto. The display apparatus 1 may be applied to any of various products such as a television, a laptop computer, a monitor, an advertisement board, or an Internet of things (IoT) product as well as a portable electronic device such as a mobile phone, a smartphone, a tablet personal computer (PC), a mobile communication terminal, an electronic organizer, an electronic book, a portable multimedia player (PMP), a navigation device, or an ultra-mobile PC (UMPC). Also, the display apparatus 1 according to an embodiment may be applied to a wearable device such as a smart watch, a watch phone, a glasses-type display, or a head-mounted display (HMD). Also, the display apparatus 1 according to an embodiment may be applied to a center information display (CID) located on an instrument panel, a center fascia, or a dashboard of a vehicle, a room mirror display replacing a side-view mirror of a vehicle, or a display screen located on the back of a front seat for a person in a back seat of a vehicle.

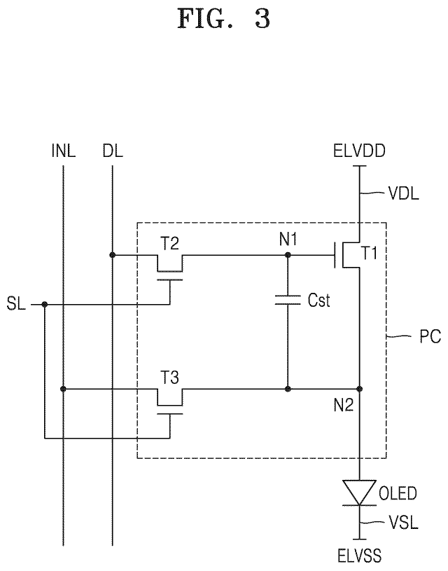

FIG. 3 is an equivalent circuit diagram illustrating a sub-pixel circuit provided in a display apparatus, according to an embodiment.

Referring to FIG. 3, a sub-pixel circuit PC may include a plurality of thin-film transistors and at least one capacitor. In an embodiment, the pixel circuit PC may include a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may be an oxide semiconductor thin-film transistor including a semiconductor layer comprising an oxide semiconductor, or may be a silicon semiconductor thin-film transistor including a semiconductor layer comprising polysilicon. Each thin-film transistor may include a first electrode and a second electrode, and according to a type of each thin-film transistor, the first electrode may be one of a source electrode and a drain electrode and the second electrode may be the other of the source electrode and the drain electrode. Also, each thin-film transistor may include a gate electrode.

The first thin-film transistor T1 may be a driving thin-film transistor. The first electrode of the first thin-film transistor T1 may be connected to a driving voltage line VDL that supplies a driving power supply voltage ELVDD, and the second electrode of the first thin-film transistor T1 may be connected to a pixel electrode of an organic light-emitting diode OLED. The gate electrode of the first thin-film transistor T1 may be connected to a first node N1. The first thin-film transistor T1 may control the amount of current flowing through the organic light-emitting diode OLED from the driving power supply voltage ELVDD in response to a voltage of the first node N1.

The second thin-film transistor T2 may be a switching thin-film transistor. The first electrode of the second thin-film transistor T2 may be connected to a data line DL, and the second electrode of the second thin-film transistor T2 may be connected to the first node N1. The gate electrode of the second thin-film transistor T2 may be connected to a scan line SL. The second thin-film transistor T2 may be turned on in response to a scan signal applied to the scan line SL, and electrically connect the data line DL to the first node N1.

The third thin-film transistor T3 may be an initialization thin-film transistor or a sensing thin-film transistor. The first electrode of the third thin-film transistor T3 may be connected to a second node N2, and the second electrode of the third thin-film transistor T3 may be connected to an initialization voltage line INL. The gate electrode of the third thin-film transistor T3 may be connected to the scan line SL.

The third thin-film transistor T3 may be turned on in response to a control signal applied to the scan line SL, and electrically connect the initialization voltage line INL to the second node N2. In an embodiment, the third thin-film transistor T3 may be turned on according to a signal received through the scan line SL, and initialize the pixel electrode of the organic light-emitting diode OLED by using an initialization voltage from the initialization voltage line INL.

In an embodiment, the third thin-film transistor T3 may be turned on in response to a scan signal applied to the scan line SL, and sense characteristic information of the organic light-emitting diode OLED. The third thin-film transistor T3 may have both a function of an initialization thin-film transistor and a function of a sensing thin-film transistor, or may have any one of these functions. An initialization operation and a sensing operation of the third thin-film transistor T3 may be performed individually or simultaneously. When the third thin-film transistor T3 has a function of a sensing thin-film transistor, the initialization voltage line INL may be referred to as a sensing line.

The storage capacitor Cst may be connected between the first node N1 and the second node N2. For example, a first capacitor electrode of the storage capacitor Cst may be connected to the gate electrode of the first thin-film transistor T1, and a second capacitor electrode of the storage capacitor Cst may be connected to the pixel electrode of the organic light-emitting diode OLED.

A counter electrode of the organic light-emitting diode OLED may be connected to a common voltage line VSL through which a common power supply voltage ELVSS is provided.

Although the sub-pixel circuit PC includes three thin-film transistors and one storage capacitor as depicted in FIG. 3, the present disclosure is not limited thereto. In an embodiment, the number of thin-film transistors or the number of storage capacitors may be changed in various ways according to a design of the sub-pixel circuit PC.

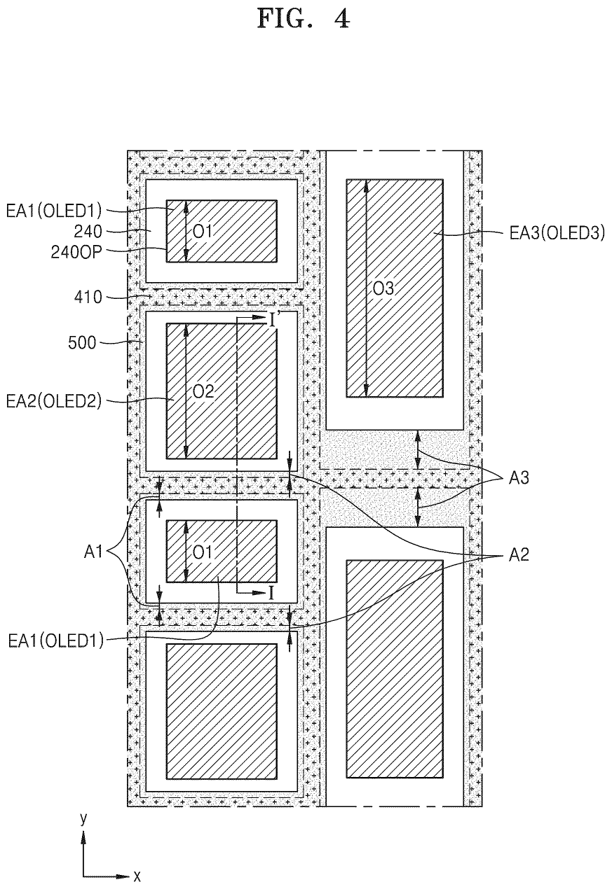

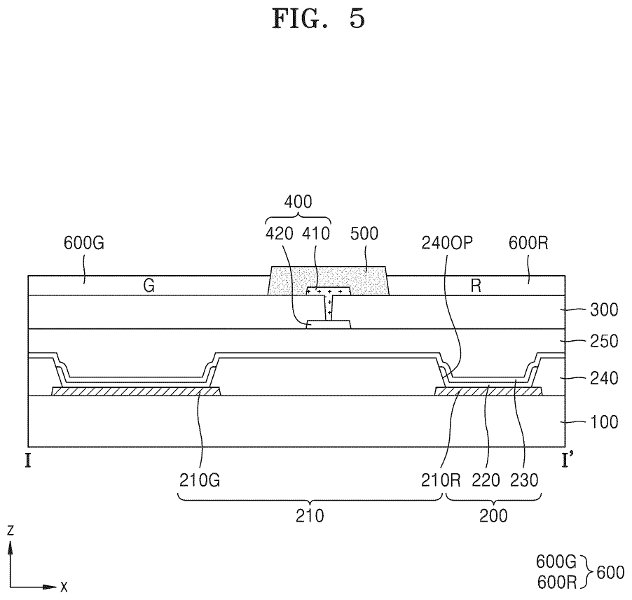

FIG. 4 is a plan view schematically illustrating a display apparatus, according to an embodiment. FIG. 5 is a schematic cross-sectional view taken along a line I-I′ of the display apparatus of FIG. 4.

Referring to FIGS. 4 and 5, the display apparatus may include a first emission area EA1, a second emission area EA2, and a third emission area EA3. The first emission area EA1, the second emission area EA2, and the third emission area EA3 which may be defined by an opening 2400P of the pixel-defining film 240. A first metal pattern 410 may be disposed on the pixel-defining film 240. The first metal patterns 410 may be arranged to surround at least a part of each of the first emission area EA1, the second emission area EA2, and the third emission area EA3. A light blocking layer 500 may be disposed to cover the first metal pattern 410. The light blocking layer 500 may be arranged to surround at least a part of each of the first emission area EA1, the second emission area EA2, and the third emission area EA3. Because the light blocking layer 500 is disposed to cover the first metal pattern 410, the first metal pattern 410 may be prevented from being visible due to external light, thereby improving the visibility and quality of the display apparatus.

A first organic light-emitting diode OLED1 may be located to correspond to the first emission area EA1, a second organic light-emitting diode OLED2 may be located to correspond to the second emission area EA2, and a third organic light-emitting diode OLED3 may be located to correspond to the third emission area EA3. The first organic light-emitting diode OLED1 may emit red light, the second organic light-emitting diode OLED2 may emit green light, and the third organic light-emitting diode OLED3 may emit blue light.

Emission layers of the first organic light-emitting diode OLED1, which is disposed in the first emission area EA1 and emits red light, the second organic light-emitting diode OLED2, which is disposed in the second emission area EA2 and emits green light, and the third organic light-emitting diode OLED3, which is disposed in the third emission area EA3 and emits blue light, may include different materials. Consequently, lifespans of the first organic light-emitting diode OLED1, the second organic light-emitting diode OLED2, and the third organic light-emitting diode OLED3 may be different from each other. Hence, the areas of the first emission area EA1 in which the first organic light-emitting diode OLED1 is located, the second emission area EA2 in which the second organic light-emitting diode OLED2 is located, and the third emission area EA3 in which the third organic light-emitting diode OLED3 is located may be different from each other. For example, the area of the first emission area EA1 in which the first organic light-emitting diode OLED1 emitting e.g., red light is disposed may be less than the area of the second emission area EA2 and the area of the third emission area EA3, the area of the second emission area EA2 in which the second organic light-emitting diode OLED2 emitting e.g., green light is disposed may be between the area of the first emission area EA1 and the area of the third emission area EA3, and the area of the third emission area EA3 in which the third organic light-emitting diode OLED3 emitting e.g., blue light is disposed may be greater than the area of the first emission area EA1 and the area of the second emission area EA2. However, the present disclosure is not limited thereto. In an embodiment, the area of the second emission area EA2 in which the second organic light-emitting diode OLED2 emitting e.g., green light is located may be less than the area of the first emission area EA1 and the area of the third emission area EA3, the area of the first emission area EA1 in which the first organic light-emitting diode OLED1 emitting e.g., red light is located may be between the area of the second emission area EA2 and the area of the third emission area EA3, and the area of the third emission area EA3 in which the third organic light-emitting diode OLED3 emitting e.g., blue light is located may be greater than the area of the first emission area EA1 and the area of the second emission area EA2.

When the lengths from an end of the light blocking layer 500 surrounding each of the first to third emission areas EA1, EA2, and EA3 to an end of the first metal patterns 410 adjacent thereto are the same, the amounts of light emitted from the first to third organic light-emitting diodes OLED1, OLED2, and OLED3, which are disposed in the first to third emission areas EA1, EA2, and EA3 respectively, and covered by the light blocking layer 500 disposed on the pixel-defining film 240 may be the same, because the area of the first emission area EA1, the area of the second emission area EA2, and the area of the third emission area EA3 are different from each other. As a result, the amounts of light emitted in side directions from the first to third organic light-emitting diodes OLED1, OLED2, and OLED3 located in the first to third emission areas EA1, EA2, and EA3 may be different from each other. This results in a difference in a viewing angle or a color change depending on each azimuth angle and not satisfying the optical characteristics of the display apparatus required by customers.

In an embodiment, a length O3 of the third emission area EA3 in a second direction (e.g., a y direction or a −y direction) may be greater than a length O1 of the first emission area EA1 in the second direction (e.g., y direction or the −y direction) and a length O2 of the second emission area EA2 in the second direction (e.g., the y direction or the −y direction). The length O1 of the first emission area EA1 in the second direction (e.g., the y direction or the −y direction) may be less than the length O2 of the second emission area EA2 in the second direction (e.g., the y direction or the −y direction) and the length O3 of the third emission area EA3 in the second direction (e.g., the y direction or the −y direction). The length O2 of the second emission area EA2 in the second direction (e.g., the y direction or the −y direction) may be between the length O1 of the first emission area EA1 in the second direction (e.g., the y direction or the −y direction) and the length O3 of the third emission area EA3 in the second direction (e.g., the y direction or the −y direction). However, the disclosure is not limited thereto.

A ratio of the length O1 of the first emission area EA1 in the second direction (e.g., the y direction or the −y direction), the length O2 of the second emission area EA2 in the second direction (e.g., the y direction or the −y direction), and the length O3 of the third emission area EA3 in the second direction (e.g., the y direction or the −y direction) may be the same as a ratio of a length A1 from an end of the light blocking layer 500, which surrounds the first emission area EA1, extending in a first direction (e.g., an x direction or a −x direction) to an end of the first metal pattern 410 adjacent thereto, a length A2 from an end of the light blocking layer 500, which surrounds the second emission area EA2, extending in the first direction (e.g., the x direction or the −x direction) to an end of the first metal pattern 410 adjacent thereto, and a length A3 from an end of the light blocking layer 500, which surrounds the third emission area EA3, extending in the first direction (e.g., the x direction or the −x direction) to an end of the first metal pattern 410 adjacent thereto.

In other words, the length A3 from an end of the light blocking layer 500, which surrounds the third emission area EA3, extending in the first direction (e.g., the x direction or the −x direction) to an end of the first metal pattern 410 adjacent thereto may be greater than the length A1 from an end of the light blocking layer 500, which surrounds the first emission area EA1, extending in the first direction (e.g., the x direction or the −x direction) to an end of the first metal pattern 410 adjacent thereto and the length A2 from an end of the light blocking layer 500, which surrounds the second emission area EA2, extending in the first direction (e.g., the x direction or the −x direction) to an end of the first metal pattern 410 adjacent thereto. The length A1 from an end of the light blocking layer 500, which surrounds the first emission area EA1, extending in the first direction (e.g., the x direction or the −x direction) to an end of the first metal pattern 410 adjacent thereto may be less than the length A2 from an end of the light blocking layer 500, which surrounds the second emission area EA2, extending in the first direction (e.g., the x direction or the −x direction) to an end of the first metal pattern 410 adjacent thereto and the length A3 from an end of the light blocking layer 500, which surrounds the third emission area EA3, extending in the first direction (e.g., the x direction or the −x direction) to an end of the first metal pattern 410 adjacent thereto. The length A2 from an end of the light blocking layer 500, which surrounds the second emission area EA2, extending in the first direction (e.g., the x direction or the −x direction) to an end of the first metal pattern 410 adjacent thereto may be between the length A1 from an end of the light blocking layer 500, which surrounds the first emission area EA1, extending in the first direction (e.g., the x direction or the −x direction) to an end of the first metal pattern 410 adjacent thereto and the length A3 from an end of the light blocking layer 500, which surrounds the third emission area EA3, extending in the first direction (e.g., the x direction or the −x direction) to an end of the first metal pattern 410 adjacent thereto.

Accordingly, the amount of light, which is emitted in a side direction from the third organic light-emitting diode OLED3 in the third emission area EA3, covered by the light blocking layer 500 may be greater than the amount of light, which is emitted in a side direction from the first organic light-emitting diode OLED1 in the first emission area EA1 or from the second organic light-emitting diode OLED2 in the second emission area EA2, covered by the light blocking layer 500. The amount of light, which is emitted in a side direction from the first organic light-emitting diode OLED1, covered by the light blocking layer 500 may be less than the amount of light, which is emitted in a side direction from the second organic light-emitting diode OLED2 or from the third organic light-emitting diode OLED3, covered by the light blocking layer 500. Also, the amount of light from the second organic light-emitting diode OLED2 covered by the light blocking layer 500 may be between the amount of light from the first organic light-emitting diode OLED1 covered by the light blocking layer 500 and the amount of light from the third organic light-emitting diode OLED3 covered by the light blocking layer 500.

In an embodiment, the lengths A1, A2, and A3 from ends of the light blocking layer 500 extending in the first direction (e.g., the x direction or the −x direction), while surrounding the first to third emission areas EA1, EA2, and EA3, to ends of the first metal pattern 410 adjacent thereto may be different from each other so that each of the amount of light, which is emitted from the first organic light-emitting diode OLED1, the second organic light-emitting diode OLED2, or the third organic light-emitting diode OLED3, covered by the light blocking layer 500 is adjusted to be different from each other. Accordingly, the amounts of light emitted in side directions from the first to third organic light-emitting diodes OLED1, OLED2, and OLED3 may be ultimately the same, and thus, a difference in a viewing angle and a color change in each azimuth angle may be prevented from occurring and the visibility and quality of the display apparatus may be improved.

Referring to FIG. 5, the display apparatus according to an embodiment may include a substrate 100, a plurality of pixel electrodes 210 disposed on the substrate 100, a second metal pattern 420 disposed on the plurality of pixel electrodes 210, a first insulating layer 300 covering the second metal pattern 420, the first metal pattern 410 disposed on the first insulating layer 300, the light blocking layer 500 covering the first metal pattern 410, and color filters 600.

The substrate 100 may include any of various materials such as a glass material, a metal material, or a plastic material such as polyethylene terephthalate (PET), polyethylene naphthalate (PEN), or polyimide. The substrate 100 may include a display area in which the plurality of pixel electrodes 210 are located and a peripheral area surrounding the display area. The substrate 100 may be rigid or flexible. When the substrate 100 is flexible, the substrate 100 may be bent or folded.

The plurality of pixel electrodes 210 may be disposed on the substrate 100. When the plurality of pixel electrodes 210 are disposed on the substrate 100, the plurality of pixel electrodes 210 may be directly disposed on the substrate 100, or various layers may be formed on the substrate 100 and the plurality of pixel electrodes 210 may be disposed on the various layers. For example, a thin-film transistor may be disposed on the substrate 100, a planarization film may cover the thin-film transistor, and the plurality of pixel electrodes 210 may be disposed on the planarization film. For convenience of explanation, FIG. 5 depicts the plurality of pixel electrodes 210 being directly disposed on the substrate 100, and the same applies to the following description for convenience of the explanation.

The plurality of pixel electrodes 210 may be (semi-)transparent electrodes or reflective electrodes. When the plurality of pixel electrodes 210 are (semi-)transparent electrodes, the plurality of pixel electrodes 210 may comprise, for example, ITO, IZO, ZnO, In2O3, IGO, or AZO. When the plurality of pixel electrodes 210 are reflective electrodes, the plurality of pixel electrodes 210 may include a reflective film comprising Ag, Mg, Al, Pt, Pd, Au, Ni, Nd, Ir, Cr, or a compound thereof and a layer comprising ITO, IZO, ZnO, In2O3, IGO, or AZO. However, the disclosure is not limited thereto, and various modifications may be made. For example, the plurality of pixel electrodes 210 may include various materials and may have a single or multi-layer structure.

The pixel-defining film 240 covering an edge of each of the plurality of pixel electrodes 210 may be further disposed on the plurality of pixel electrodes 210. The pixel-defining film 240 may define an emission area. In detail, an emission area may be defined by an opening of the pixel-defining film 240 which extends to a central portion of each of the plurality of pixel electrodes 210. The pixel-defining film 240 may include an organic insulating material, for example, a acrylic material or benzocyclobutene (BCB).

The second metal pattern 420 may be disposed on the plurality of pixel electrodes 210, and a counter electrode 230 and an encapsulation layer 250 may be disposed between the plurality of pixel electrodes 210 and the second metal pattern 420.

A display unit including the plurality of pixel electrodes 210 may include a plurality of thin-film transistors (not shown) each of which are electrically connected to the plurality of pixel electrodes 210, respectively. The display unit may be a liquid crystal display unit or an organic light-emitting display unit. The following embodiment will be described assuming that the display unit is an organic light-emitting display unit.

The counter electrode 230 facing the plurality of pixel electrodes 210 may be disposed on the plurality of pixel electrodes 210. The counter electrode 230 may be a common electrode formed on an entire surface of the substrate 100, as shown in FIG. 2.

The counter electrode 230 may be a (semi-)transparent electrode or a reflective electrode. When the counter electrode 230 is a (semi-)transparent electrode, the counter electrode 230 may include a metal having a low work function, that is, Li, Ca, LiF/Ca, LiF/Al, Al, Ag, Mg, or a compound thereof, and the (semi-)transparent conductive layer may further include ITO, IZO, ZnO, or In₂O₃. When the counter electrode 230 is a reflective electrode, the counter electrode 230 may include Li, Ca, LiF/Ca, LiF/Al, Al, Ag, Mg, or a compound thereof. A configuration and a material of the counter electrode 230 are not limited thereto, and various modifications may be made.

A plurality of intermediate layers 220 may be disposed between the plurality of pixel electrodes 210 and the counter electrode 230. The plurality of intermediate layers 220 may be located to respectively correspond to the plurality of pixel electrodes 210. Each of the plurality of intermediate layers 220 may include an emission layer (EML) that emits light according to an electrical signal, and in addition to the emission layer, the intermediate layer 220 may include a hole injection layer (HIL) disposed between the emission layer (EML) and the plurality of pixel electrodes 210, a hole transport layer (HTL), an electron transport layer (ETL) disposed between the emission layer (EML) and the counter electrode 230, and an electron injection layer (EIL). The intermediate layer 220 is not necessarily limited thereto and may have various modifications.

Each of the plurality of pixel electrodes 210 in association with the intermediate layer 220 and the counter electrode 230 functions as an organic light-emitting device 200. Each organic light-emitting device 200 may be a pixel (or a sub-pixel).

The encapsulation layer 250 may be disposed on the counter electrode 230. Although not shown in FIG. 5, the encapsulation layer 250 may have a multi-layer structure in which at least one organic film and at least one inorganic film are stacked in turns. The encapsulation layer 250 protects the display unit from external moisture permeation.

In an embodiment, a functional layer such as a polarization layer may be further disposed on the encapsulation layer 250.

The first metal pattern 410 may be disposed on the plurality of pixel electrodes 210. When the first metal pattern 410 is disposed on the plurality of pixel electrodes 210, it may mean that the intermediate layer 220 and the counter electrode 230 are disposed on the plurality of pixel electrodes 210, the encapsulation layer 250 covers the counter electrode 230, and the first metal pattern 410 is provided on the encapsulation layer 250. In an embodiment, a planarization film including an insulating material may be further disposed between the encapsulation layer 250 and the first metal pattern 410 to planarize a top surface of the encapsulation layer 250.

The second metal pattern 420 may be disposed between the plurality of pixel electrodes 210. Because an area where the plurality of pixel electrodes 210 are disposed is a pixel area where an image is displayed, the second metal pattern 420 may be disposed between the plurality of pixel electrodes 210 where the plurality of pixel electrodes 210 are not located.

The second metal pattern 420 may be a wiring 400 for a touch. That is, the touch screen may include a plurality of sensor units, and the second metal pattern 420 may function as a connection wiring for connecting the plurality of sensor units. Accordingly, the second metal pattern 420 may include a conductive metal material.

The first insulating layer 300 may be disposed on the second metal pattern 420. The first insulating layer 300 may electrically insulate the first metal pattern 410 from the second metal pattern 420 as described below. The first insulating layer 300 may include an insulating material. When the first insulating layer 300 is formed of an inorganic insulating material, the first insulating layer 300 may include, for example, silicon oxide, silicon nitride, or silicon oxynitride, and when the first insulating layer 300 is formed of an organic insulating material, the first insulating layer 300 may include, for example, an acrylic organic material or benzocyclobutene (BCB).

The first metal pattern 410 may be disposed on the first insulating layer 300. The first metal pattern 410 may be formed to overlap the second metal pattern 420, and may be located between the plurality of pixel electrodes 210, like the second metal pattern 420. The second metal pattern 420 and the first metal pattern 410 may be electrically connected to each other through a contact hole extending through the first insulating layer 300.

The first metal pattern 410 may be the wiring 400 for a touch screen, like the second metal pattern 420. That is, the touch screen may include a plurality of sensor units, and the first metal pattern 410 may function as a connection wiring for connecting the plurality of sensor units. Accordingly, the first metal pattern 410 may include a conductive metal material.

The light blocking layer 500 may be disposed on the first metal pattern 410. The light blocking layer 500 may cover the first metal pattern 410, and may function as a black matrix that prevents external light from being reflected on the first metal pattern 420 and defines a light area where each pixel emits light. The light blocking layer 500 may include a light blocking material, for example, a resin or paste including organic resin, glass paste, and black pigment, metal particles such as nickel, aluminum, molybdenum, or an alloy thereof, metal oxide particles such as chromium oxide, or metal nitride particles such as chromium nitride.

The light blocking layer 500 may be formed to cover the first metal pattern 410 and may include first openings which extends to at least a part of the first insulating layer 300 located under the light blocking layer 500. The first openings may respectively correspond to the plurality of pixel electrodes 210.

The color filters 600 may be disposed in the first openings of the light blocking layer 500 to respectively correspond to the plurality of pixel electrodes 210. The color filters 600 may pass light of a specific wavelength band.

The plurality of pixel electrodes 210 may include a first pixel electrode 210R, a second pixel electrode 210G, and a third pixel electrode 210B (not shown). The color filters 600 may include a first color filter 600R through which light of a first wavelength band passes, a second color filter 600G through which light of a second wavelength band passes, and a third color filter 600B (not shown) through which light of a third wavelength band passes. For example, the first color filter 600R may be a red color filter through which red light passes, the second color filter 600G may be a green color filter through which green light passes, and the third color filter 600B may be a blue color filter through which blue light passes. The first color filter 600R may be disposed to overlap the first pixel electrode 210R, the second color filter 600G may be disposed to overlap the second pixel electrode 210G, and the third color filter 600B may be disposed to overlap the third pixel electrode 210B.

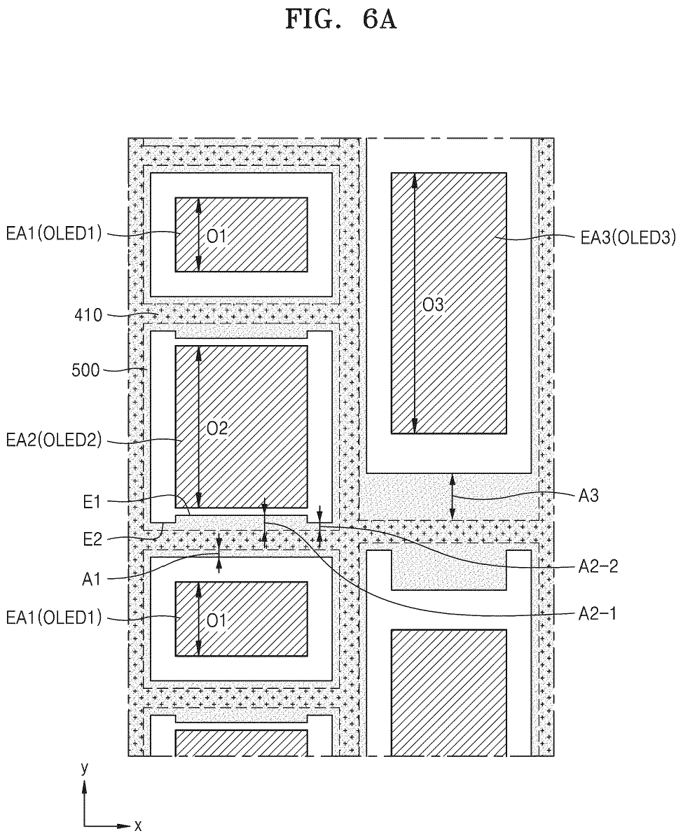

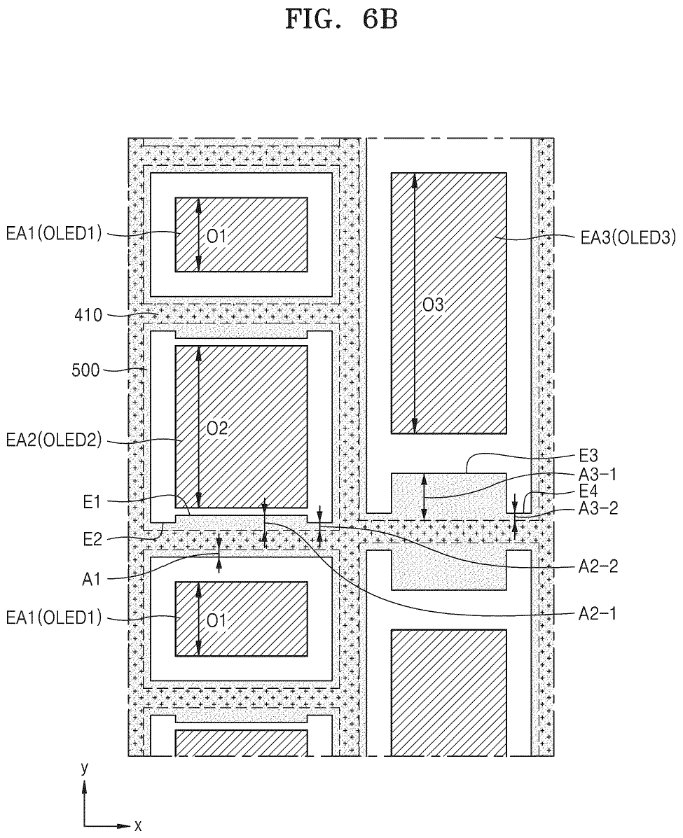

FIGS. 6A and 6B are plan views schematically illustrating a display apparatus, according to an embodiment.

Referring to FIG. 6A, the first metal pattern 410 may be located to surround at least a part of the first emission area EA1, at least a part of the second emission area EA2, and at least a part of the third emission area EA3. The light blocking layer 500 may cover the first metal pattern 410 and may be arranged to surround at least a part of the first emission area EA1, at least a part of the second emission area EA2, and at least a part of the third emission area EA3. The light blocking layer 500 extending in the first direction (e.g., the x direction or the −x direction) and surrounding the second emission area EA2 may include a first edge E1 and a second edge E2. When the display apparatus is viewed in the second direction (e.g., the y direction or the −y direction), the first edge E1 of the light blocking layer 500 may overlap an edge of the second emission area EA2 extending in the first direction (e.g., the x direction or the −x direction), and the second edge E2 of the light blocking layer 500 may not overlap the edge of the second emission area EA2 extending in the first direction (e.g., the x direction or the −x direction). That is, the first edge E1 is protruded from the light blocking layer 500 which surrounds the second emission area EA2 to be disposed closer to the edge of the second emission area EA2, in a plan view, than the second edge E2 of the light blocking layer 500, as depicted in FIG. 6A. A length A2-1 from an end of the first edge E1 of the light blocking layer 500 surrounding the second emission area EA2 to an end of the first metal pattern 410 adjacent thereto and a length A2-2 from an end of the second edge E2 of the light blocking layer 500 to an end of the first metal pattern 410 adjacent thereto may be different from each other. The first edge E1 of the light blocking layer 500 extending in the first direction (e.g., the x direction or the −x direction) while surrounding the second emission area EA2 is formed close to the edge of the second emission area EA2 extending in the first direction (e.g., the x direction or the −x direction), and thus, may affect the amount of light emitted in a side direction from the second organic light-emitting diode OLED2 of the second emission area EA2.

In an embodiment, the length O3 of the third emission area EA3 in the second direction (e.g., the y direction or the −y direction) may be greater than the length O1 of the first emission area EA1 in the second direction (e.g., the y direction or the −y direction) and the length O2 of the second emission area EA2 in the second direction (e.g., the y direction or the −y direction). The length O1 of the first emission area EA1 in the second direction (e.g., the y direction or the −y direction) may be less than the length O2 of the second emission area EA2 in the second direction (e.g., the y direction or the −y direction) and the length O3 of the third emission area EA3 in the second direction (e.g., the y direction or the −y direction). The length O2 of the second emission area EA2 in the second direction (e.g., the y direction or the −y direction) may be between the length O1 of the first emission area EA1 in the second direction (e.g., the y direction or the −y direction) and the length O3 of the third emission area EA3 in the second direction (e.g., the y direction or the −y direction). However, the disclosure is not limited thereto.

A ratio of the length O1 of the first emission area EA1 in the second direction (e.g., the y direction or the −y direction), the length O2 of the second emission area EA2 in the second direction (e.g., the y direction or the −y direction), and the length O3 of the third emission area EA3 in the second direction (e.g., the y direction or the −y direction) may be the same as a ratio of the length A1 from an end of the light blocking layer 500, which surrounds the first emission area EA1, extending in the first direction (e.g., the x direction or the −x direction) to an end of the first metal pattern 410 adjacent thereto, the length A2-1 from an end of the first edge E1 of the light blocking layer 500 surrounding the second emission area EA2 to an end of the first metal pattern 410 adjacent thereto, and the length A3 from an end of the light blocking layer 500, which surrounds the third emission area EA3, extending in the first direction (e.g., the x direction or the −x direction) to an end of the first metal pattern 410 adjacent thereto. Because the second edge E2 of the light blocking layer 500 extending in the first direction (e.g., the x direction or the −x direction) while surrounding the second emission area EA2 does not affect the amount of light emitted in a side direction from the second organic light-emitting diode OLED2, a length from the second edge E2 of the light blocking layer 500 to an end of the first metal pattern 410 adjacent thereto may not be limited.

In other words, the length A3 from an end of the light blocking layer 500, which surrounds the third emission area EA3, extending in the first direction (e.g., the x direction or the −x direction) to an end of the first metal pattern 410 adjacent thereto may be greater than the length A1 from an end of the light blocking layer 500, which surrounds the first emission area EA1, extending in the first direction (e.g., the x direction or the −x direction) to an end of the first metal pattern 410 adjacent thereto and the length A2-1 from an end of the first edge E1 of the light blocking layer 500 surrounding the second emission area EA2 to an end of the first metal pattern 410 adjacent thereto. The length A1 from an end of the light blocking layer 500, which surrounds the first emission area EA1, extending in the first direction (e.g., the x direction or the −x direction) to an end of the first metal pattern 410 adjacent thereto may be less than the length A2-1 from an end of the first edge E1 of the light blocking layer 500 surrounding the second emission area EA2 to an end of the first metal pattern 410 adjacent thereto and the length A3 from an end of the light blocking layer 500, which surrounds the third emission area EA3, extending in the first direction (e.g., the x direction or the −x direction) to an end of the first metal pattern 410 adjacent thereto. The length A2-1 from an end of the first edge E1 of the light blocking layer 500 surrounding the second emission area EA2 to an end of the first metal pattern 410 adjacent thereto may be between the length A1 from an end of the light blocking layer 500, which surrounds the first emission area EA1, extending in the first direction (e.g., the x direction or the −x direction) to an end of the first metal pattern 410 adjacent thereto and the length A3 from an end of the light blocking layer 500, which surrounds the third emission area EA3, extending in the first direction (e.g., the x direction or the −x direction) to an end of the first metal pattern 410 adjacent thereto.

Accordingly, the amount of light, which is emitted in a side direction from the third organic light-emitting diode OLED3 in the third emission area EA3, covered by the light blocking layer 500 may be greater than the amount of light, which is emitted in a side direction from the first organic light-emitting diode OLED1 in the first emission area EA1 or from the second organic light-emitting diode OLED2 in the second emission area EA2, covered by the light blocking layer 500. The amount of light from the first organic light-emitting diode OLED1 covered by the light blocking layer 500 may be less than the amount of light from the second organic light-emitting diode OLED2 or from the third organic light-emitting diode OLED3 covered by the light blocking layer 500. Also, the amount of light from the second organic light-emitting diode OLED2 covered by the light blocking layer 500 may be between the amount of light from the first organic light-emitting diode OLED1 covered by the light blocking layer 500 and the amount of light from the third organic light-emitting diode OLED3 covered by the light blocking layer 500.

In an embodiment, the lengths A1, A2-1, and A3 from ends of the light blocking layer 500 extending in the first direction (e.g., the x direction or the −x direction) while surrounding the first to third emission areas EA1, EA2, and EA3 to ends of the first metal pattern 410 adjacent thereto may be different from each other so that each of the amount of light, which is emitted from the first organic light-emitting diode OLED1, the second organic light-emitting diode OLED2, or the third organic light-emitting diode OLED3, covered by the light blocking layer 500 is adjusted to be different from each other. Accordingly, the amounts of light emitted in side directions from the first to third organic light-emitting diodes OLED1, OLED2, and OLED3 may be the same, and thus, a difference in a viewing angle and a color change in each azimuth angle may be prevented from occurring and the visibility and quality of the display apparatus may be improved.

Referring to FIG. 6B, the light blocking layer 500, which surrounds the third emission area EA3, extending in the first direction (e.g., the x direction or the −x direction) may include a third edge E3 and a fourth edge E4. When the display apparatus is viewed in the second direction (e.g., the y direction or the −y direction), the third edge E3 of the light blocking layer 500 may overlap an edge of the third emission area EA3 extending in the first direction (e.g., the x direction or the −x direction), and the fourth edge E4 of the light blocking layer 500 may not overlap the edge of the third emission area EA3 extending in the first direction (e.g., the x direction or the −x direction). That is, the third edge E3 is protruded from the light blocking layer 500 which surrounds the third emission area EA3 to be disposed closer to the edge of the third emission area EA3, in a plan view, than the fourth edge E4 of the light blocking layer 500, as depicted in FIG. 6B. A length A3-1 from an end of the third edge E3 of the light blocking layer 500 surrounding the third emission area EA3 to an end of the first metal pattern 410 adjacent thereto and a length A3-2 from an end of the fourth edge E4 of the light blocking layer 500 to an end of the first metal pattern 410 adjacent thereto may be different from each other. The third edge E3 of the light blocking layer 500 extending in the first direction (e.g., the x direction or the −x direction) while surrounding the third emission area EA3 is formed close to the edge of the third emission area EA3 extending in the first direction (e.g., the x direction or the −x direction), and thus, may affect the amount of light emitted obliquely from the third organic light-emitting diode OLED3 of the third emission area EA3.

In an embodiment, a ratio of the length O1 of the first emission area EA1 in the second direction (e.g., the y direction or the −y direction), the length O2 of the second emission area EA2 in the second direction (e.g., the y direction or the −y direction), and the length O3 of the third emission area EA3 in the second direction (e.g., the y direction or the −y direction) may be the same as a ratio of the length A1 from an end of the light blocking layer 500, which surrounds the first emission area EA1, extending in the first direction (e.g., the x direction or the −x direction) to an end of the first metal pattern 410 adjacent thereto, the length A2-1 from an end of the first edge E1 of the light blocking layer 500 surrounding the second emission area EA2 to an end of the first metal pattern 410 adjacent thereto, and the length A3-1 from an end of the third edge E3 of the light blocking layer 500 surrounding the third emission area EA3 to an end of the first metal pattern 410 adjacent thereto. Because the second edge E2 of the light blocking layer 500 extending in the first direction (e.g., the x direction or the −x direction) while surrounding the second emission area EA2 and the fourth edge E4 of the light blocking layer 500 extending in the first direction (e.g., the x direction or the −x direction) while surrounding the third emission area EA3 do not affect the amount of light emitted in a side direction from the second organic light-emitting diode OLED2 or the third organic light-emitting diode OLED3, the length A2-2 from the second edge E2 of the light blocking layer 500 to an end of the first metal pattern 410 adjacent thereto and the length A3-2 from the fourth edge E4 to an end of the first metal pattern 410 adjacent thereto may not be limited.

In other words, the length A3-1 from an end of the third edge E3 of the light blocking layer 500 surrounding the third emission area EA3 to an end of the first metal pattern 410 adjacent thereto may be greater than the length A1 from an end of the light blocking layer 500, which surrounds the first emission area EA1, extending in the first direction (e.g., the x direction or the −x direction) to an end of the first metal pattern 410 adjacent thereto and the length A2-1 from an end of the first edge E1 of the light blocking layer 500 surrounding the second emission area EA2 to an end of the first metal pattern 410 adjacent thereto. The length A1 from an end of the light blocking layer 500, which surrounds the first emission area EA1, extending in the first direction (e.g., the x direction or the −x direction) to an end of the first metal pattern 410 adjacent thereto may be less than the length A2-1 from an end of the first edge E1 of the light blocking layer 500 surrounding the second emission area EA2 to an end of the first metal pattern 410 adjacent thereto and the length A3-1 from an end of the third edge E3 of the light blocking layer 500 surrounding the third emission area EA3 to an end of the first metal pattern 410 adjacent thereto. The length A2-1 from an end of the first edge E1 of the light blocking layer 500 surrounding the second emission area EA2 to an end of the first metal pattern 410 adjacent thereto may be between the length A1 from an end of the light blocking layer 500, which surrounds the first emission area EA1, extending in the first direction (e.g., the x direction or the −x direction) to an end of the first metal pattern 410 adjacent thereto and the length A3-1 from an end of the third edge E3 of the light blocking layer 500 surrounding the third emission area EA3 to an end of the first metal pattern 410 adjacent thereto.

Accordingly, the amount of light, which is emitted in a side direction from the third organic light-emitting diode OLED3 in the third emission area EA3, covered by the light blocking layer 500 may be greater than the amount of light, which is emitted in a side direction from the first organic light-emitting diode OLED1 in the first emission area EA1 or from the second organic light-emitting diode OLED2 in the second emission area EA2, covered by the light blocking layer 500. The amount of light, which is emitted in a side direction from the first organic light-emitting diode OLED1, covered by the light blocking layer 500 may be less than the amount of light that is emitted from the second organic light-emitting diode OLED2 or from the third organic light-emitting diode OLED3, covered by the light blocking layer 500. Also, the amount of light from the second organic light-emitting diode OLED3 covered by the light blocking layer 500 may be between the amount of light from the first organic light-emitting diode OLED1 covered by the light blocking layer 500 and the amount of light from the third organic light-emitting diode OLED3 covered by the light blocking layer 500.

The lengths A1, A2-1, and A3-1 from ends of the light blocking layer extending in the first direction (e.g., the x direction or the −x direction) while surrounding the first to third emission areas EA1, EA2, and EA3 to ends of the first metal pattern 410 adjacent thereto may be different from each other so that each of the amount of light, which is emitted from the first organic light-emitting diode OLED1, the second organic light-emitting diode OLED2, or the third organic light-emitting diode OLED3, covered by the light blocking layer 500 is adjusted to be different from each other. Accordingly, the amounts of light emitted in side directions from the first to third organic light-emitting diodes OLED1, OLED2, and OLED3 may be the same, and thus, a difference in a viewing angle and a color change in each azimuth angle may be prevented from occurring and the visibility and quality of the display apparatus may be improved.

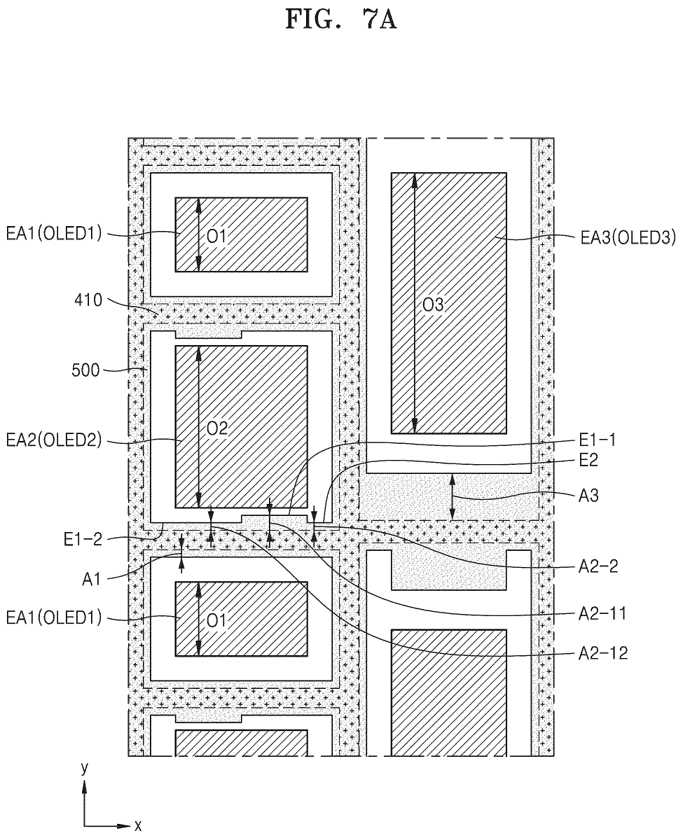

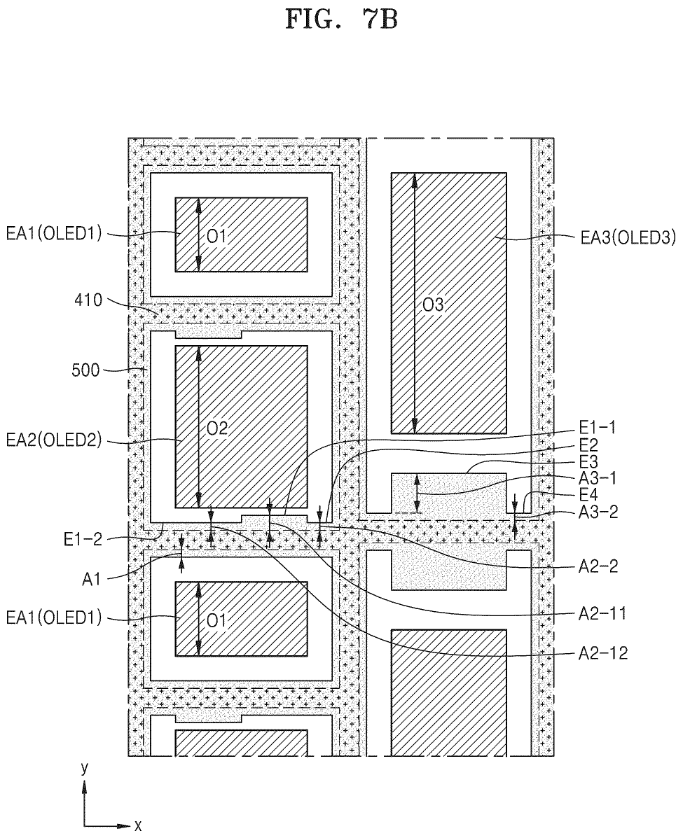

FIGS. 7A and 7B are plan views schematically illustrating a display apparatus, according to an embodiment.

Referring to FIG. 7A, the first metal pattern 410 may be arranged to surround at least a part of the first emission area EA1, at least a part of the second emission area EA2, and at least a part of the third emission area EA3. The light blocking layer 500 may cover the first metal pattern 410 and may be arranged to surround at least a part of the first emission area EA1, at least a part of the second emission area EA2, and at least a part of the third emission area EA3. When the display apparatus is viewed in the second direction (e.g., the y direction or the −y direction), the light blocking layer 500, which surrounds the second emission area EA2, extending in the first direction (e.g., the x direction or the −x direction) may include the first edge E1 overlapping an edge of the second emission area EA2 extending in the first direction (e.g., the x direction or the −x direction) and the second edge E2 not overlapping the edge of the second emission area EA2 extending in the first direction (e.g., the x direction or the −x direction). That is, the first edge E1 is protruded from the light blocking layer 500 which surrounds the second emission area EA2 to be disposed closer to the edge of the second emission area EA2, in a plan view, than the second edge E2 of the light blocking layer 500, as depicted in FIG. 7A.

The first edge E1 of the light blocking layer 500 surrounding the second emission area EA2 may include a 1-1 edge E1-1 and a 1-2 edge E1-2. A length A2-11 from an end of the 1-1 edge E1-1 of the light blocking layer 500 surrounding the second emission area EA2 to an end of the first metal pattern 410 adjacent thereto and a length A2-12 from an end of the 1-2 edge E1-2 of the light blocking layer 500 to an end of the first metal pattern 410 adjacent thereto may be different from each other.

In an embodiment, the length O3 of the third emission area EA3 in the second direction (e.g., the y direction or the −y direction) may be greater than the length O1 of the first emission area EA1 in the second direction (e.g., the y direction or the −y direction) and the length O2 of the second emission area EA2 in the second direction (e.g., the y direction or the −y direction). The length O1 of the first emission area EA1 in the second direction (e.g., the y direction or the −y direction) may be less than the length O2 of the second emission area EA2 in the second direction (e.g., the y direction or the −y direction) and the length O3 of the third emission area EA3 in the second direction (e.g., the y direction or the −y direction). The length O2 of the second emission area EA2 in the second direction (e.g., the y direction or the −y direction) may be between the length O1 of the first emission area EA1 in the second direction (e.g., the y direction or the −y direction) and the length O3 of the third emission area EA3 in the second direction (e.g., the y direction or the −y direction). However, the present disclosure is not limited thereto.

A ratio of the length O1 of the first emission area EA1 in the second direction (e.g., the y direction or the −y direction), the length O2 of the second emission area EA2 in the second direction (e.g., the y direction or the −y direction), and the length O3 of the third emission area EA3 in the second direction (e.g., the y direction or the −y direction) may be the same as a ratio of the length A1 from an end of the light blocking layer 500, which surrounds the first emission area EA1, extending in the first direction (e.g., the x direction or the −x direction) to an end of the first metal pattern 410 adjacent thereto, the length A2-11 from an end of the 1-1 edge E1-1 of the light blocking layer 500 surrounding the second emission area EA2 to an end of the first metal pattern 410 adjacent thereto, and the length A3 from an end of the light blocking layer 500, which surrounds the third emission area EA3, extending in the first direction (e.g., the x direction or the −x direction) to an end of the first metal pattern 410 adjacent thereto.

In other words, the length A3 from an end of the light blocking layer 500, which surrounds the third emission area EA3, extending in the first direction (e.g., the x direction or the −x direction) to an end of the first metal pattern 410 adjacent thereto may be greater than the length A1 from an end of the light blocking layer 500, which surrounds the first emission area EA1, extending in the first direction (e.g., the x direction or the −x direction) to an end of the first metal pattern 410 adjacent thereto and the length A2-11 from an end of the 1-1 edge E1-1 of the light blocking layer 500 surrounding the second emission area EA2 to an end of the first metal pattern 410 adjacent thereto. The length A1 from an end of the light blocking layer 500, which surrounds the first emission area EA1, extending in the first direction (e.g., the x direction or the −x direction) to an end of the first metal pattern 410 adjacent thereto may be less than the length A2-11 from an end of the 1-1 edge E1-1 of the light blocking layer 500 surrounding the second emission area EA2 to an end of the first metal pattern 410 adjacent thereto and the length A3 from an end of the light blocking layer 500, which surrounds the third emission area EA3, extending in the first direction (e.g., the x direction or the −x direction) to an end of the first metal pattern 410 adjacent thereto. The length A2-11 from an end of the 1-1 edge E1-1 of the light blocking layer 500 surrounding the second emission area EA2 to an end of the first metal pattern 410 adjacent thereto may be between the length A1 from an end of the light blocking layer 500, which surrounds the first emission area EA1, extending in the first direction (e.g., the x direction or the −x direction) to an end of the first metal pattern 410 adjacent thereto and the length A3 from an end of the light blocking layer 500, which surrounds the third emission area EA3, extending in the first direction (e.g., the x direction or the −x direction) to an end of the first metal pattern 410 adjacent thereto.

Accordingly, the amount of light, which is emitted in a side direction from the third organic light-emitting diode OLED3 in the third emission area EA3, covered by the light blocking layer 500 may be greater than the amount of light, which is emitted in a side direction from the first organic light-emitting diode OLED1 in the first emission area EA1 or from the third organic light-emitting diode OLED3 in the third emission area EA3, covered by the light blocking layer 500. The amount of light, which is emitted in a side direction from the first organic light-emitting diode OLED1, covered by the light blocking unit 500 may be less than the amount of light, which is emitted in a side direction from the second organic light-emitting diode OLED2 or from the third organic light-emitting diode OLED3, covered by the light blocking layer 500. Also, the amount of light, which is emitted in a side direction from the second organic light-emitting diode OLED, covered by the blocking layer 500 may be between the amount of light from the first organic light-emitting diode OLED1 covered by the light blocking layer 500 and the amount of light from the third organic light-emitting diode OLED3 covered by the light blocking layer 500.

In an embodiment, the lengths A1, A2-11, and A3 from ends of the light blocking layer 500 extending in the first direction (e.g., the x direction or the −x direction) while surrounding the first to third emission areas EA1, EA2, and EA3 to ends of the first metal pattern 410 adjacent thereto may be different from each other so that each of the amount of light, which is emitted from the first organic light-emitting diode OLED1, the second organic light-emitting diode OLED2, the third organic light-emitting diode OLED3, covered by the light blocking layer 500 is adjusted to be different from each other. Accordingly, the amounts of light emitted in side directions from the first to third organic light-emitting diodes OLED1, OLED2, and OLED3 may be the same, and thus, a difference in a viewing angle and a color change in each azimuth angle may be prevented from occurring and the visibility and quality of the display apparatus may be improved.

In an embodiment, the length A2-12 from an end of the 1-2 edge E1-2 of the light blocking layer 500 surrounding the second emission area EA2 to an end of the first metal pattern 410 adjacent thereto may be less than the length A2-11 from an end of the 1-1 edge E1-1 of the light blocking layer 500 surrounding the second emission area EA2 to an end of the first metal pattern 410 adjacent thereto. Because the length A2-12 from an end of the 1-2 edge E1-2 of the light blocking layer 500 to an end of the first metal pattern 410 adjacent thereto is less than the length A2-11 from an end of the 1-1 edge E1-1 to an end of the first metal pattern 410 adjacent thereto, the amount of light emitted in a side direction from the second organic light-emitting diode OLED2 of the second emission area EA2 may be secured, thereby preventing a decrease in a luminance ratio of a side surface to a front surface of the display apparatus.

Referring to FIG. 7B, the light blocking layer 500, which surrounds the third emission area EA3, extending in the first direction (e.g., the x direction or the −x direction) may include the third edge E3 and the fourth edge E4. When the display apparatus is viewed in the second direction (e.g., the y direction or the −y direction), the third edge E3 of the light blocking layer 500 may overlap an edge of the third emission area EA3 extending in the first direction (e.g., the x direction or the −x direction), and the fourth edge E4 of the light blocking layer 500 may not overlap the edge of the third emission area EA3 extending in the first direction (e.g., the x direction or the −x direction). That is, the third edge E3 is protruded from the light blocking layer 500 which surrounds the third emission area EA3 to be disposed closer to the edge of the third emission area EA3, in a plan view, than the fourth edge E4 of the light blocking layer 500, as depicted in FIG. 7B. A length A3-1 from an end of the third edge E3 of the light blocking layer 500 surrounding the third emission area EA3 to an end of the first metal pattern 410 adjacent thereto and a length A3-2 from an end of the fourth edge E4 of the light blocking layer 500 to an end of the first metal pattern 410 adjacent thereto may be different from each other. The third edge E3 of the light blocking layer 500 extending in the first direction (e.g., the x direction or the −x direction) while surrounding the third emission area EA3 is formed close to the edge of the third emission area EA3 extending in the first direction (e.g., the x direction or the −x direction), and thus, may affect the amount of light emitted in a side direction from the third organic light-emitting diode OLED3 of the third emission area EA3.

In an embodiment, a ratio of the length O1 of the first emission area EA1 in the second direction (e.g., the y direction or the −y direction), the length O2 of the second emission area EA2 in the second direction (e.g., the y direction or the −y direction), and the length O3 of the third emission area EA3 in the second direction (e.g., the y direction or the −y direction) may be the same as a ratio of the length A1 from an end of the light blocking layer 500, which surrounds the first emission area EA1, extending in the first direction (e.g., the x direction or the −x direction) to an end of the first metal pattern 410 adjacent thereto, the length A2-11 from an end of the 1-1 edge E1-1 of the light blocking layer 500 surrounding the second emission area EA2 to an end of the first metal pattern 410 adjacent thereto, and the length A3-1 from an end of the third edge E3 of the light blocking layer 500 surrounding the third emission area EA3 to an end of the first metal pattern 410 adjacent thereto. Because the fourth edge E4 of the light blocking layer 500 extending in the first direction (e.g., the x direction or the −x direction) while surrounding the third emission area EA3 does not affect the amount of light emitted in a side direction from the third organic light-emitting diode OLED3, the length A3-2 from the fourth edge E4 of the light blocking layer 500 to an end of the first metal pattern 410 adjacent thereto may not be limited.

In other words, the length A3-1 from an end of the third edge E3 of the light blocking layer 500 surrounding the third emission area EA3 to an end of the first metal pattern 410 adjacent thereto may be greater than the length A1 from an end of the light blocking layer 500, which surrounds the first emission area EA1, extending in the first direction (e.g., the x direction or the −x direction) to an end of the first metal pattern 410 adjacent thereto and the length A2-11 from an end of the 1-1 edge E1-1 of the light blocking layer 500 surrounding the second emission area EA2 to an end of the first metal pattern 410 adjacent thereto. The length A1 from an end of the light blocking layer 500, which surrounds the first emission area EA1, extending in the first direction (e.g., the x direction or the −x direction) to an end of the first metal pattern 410 adjacent thereto may be less than the length A2-11 from an end of the 1-1 edge E1-1 of the light blocking layer 500 surrounding the second emission area EA2 to an end of the first metal pattern 410 adjacent thereto and the length A3-1 from an end of the third edge E3 of the light blocking layer 500 surrounding the third emission area EA3 to an end of the first metal pattern 410 adjacent thereto.

Accordingly, the amount of light, which is emitted in a side direction from the third organic light-emitting diode OLED3 in the third emission area EA3, covered by the light blocking layer 500 may be greater than the amount of light, which is emitted in a side direction from the first organic light-emitting diode OLED1 in the first emission area EA1 or from the second organic light-emitting diode OLED2 in the second emission area EA2, covered by the light blocking layer 500. The amount of light, which is emitted in a side direction from the first organic light-emitting diode OLED1, covered by the light blocking layer 500 may be less than the amount of light, which is emitted from the second organic light-emitting diode OLED2 or from the third organic light-emitting diode OLED3, covered by the light blocking layer 500. Also, the amount of light from the second organic light-emitting diode OLED2 covered by the light blocking layer 500 may be between the amount of light from the first organic light-emitting diode OLED1 covered by the light blocking layer 500 from among light emitted to sides from the first organic light-emitting diode OLED1 and the amount of light from the third organic light-emitting diode OLED3 covered by the light blocking layer 500.

The lengths A1, A2-11, and A3-1 from ends of the light blocking layer 500 extending in the first direction (e.g., the x direction or the −x direction) while surrounding the first to third emission areas EA1, EA2, and EA3 to ends of the first metal pattern 410 adjacent thereto may be different from each other so that each of the amount of light, which is emitted from the first organic light-emitting diode OLED1, the second organic light-emitting diode OLED2, or the third organic light-emitting diode OLED3, covered by the light blocking layer 500 is adjusted to be different from each other. Accordingly, the amounts of light emitted in side directions from the first to third organic light-emitting diodes OLED1, OLED2, and OLED3 may be the same, and thus, a difference in a viewing angle and a color change in each azimuth angle may be prevented from occurring and the visibility and reliability of the display apparatus may be improved.

According to an embodiment of the present disclosure as described above, a display apparatus with improved reliability and quality may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While the present disclosure has been described with reference to the drawings and embodiments thereof, it will be understood by one of ordinary skill in the art that various changes in form and details may be made thereto without departing from the spirit and scope of the present disclosure as set forth in the following claims.

What is claimed is:

1. A display apparatus comprising:
a substrate comprising a first emission area, a second emission area, and a third emission area;
a pixel-defining film disposed on the substrate and comprising an opening;
a first metal pattern disposed on the pixel-defining film; and
a light blocking layer covering the first metal pattern and arranged to surround at least a part of each of the first, second, and third emission areas,
wherein a ratio of a length of the first emission area in a first direction, a length of the second emission area in the first direction, and a length of the third emission area in the first direction is same as a ratio of a length from an end of the light blocking layer extending in a second direction intersecting the first direction and surrounding the first emission area to an end of the adjacent first metal pattern, a length from an end of the light blocking layer extending in the second direction and surrounding the second emission area to an end of the adjacent first metal pattern, and a length from an end of the light blocking layer extending in the second direction and surrounding the third emission area to an end of the adjacent first metal pattern.

2. The display apparatus of claim 1, wherein the first metal pattern is arranged to surround at least a part of each of the first, second, and third emission areas.

3. The display apparatus of claim 1, wherein the first emission area, the second emission area, and the third emission area are each defined by the opening of the pixel-defining film.

4. The display apparatus of claim 1, further comprising a first organic light-emitting diode, a second organic light-emitting diode, and a third organic light-emitting diode,
wherein each of the first organic light-emitting diode, the second organic light-emitting diode, and the third organic light-emitting diode comprises a pixel electrode disposed to correspond to the opening of the pixel-defining film, an emission layer disposed on the pixel electrode, and a counter electrode disposed on the emission layer.

5. The display apparatus of claim 4, wherein the first organic light-emitting diode is configured to emit red light, the second organic light-emitting diode is configured to emit green light, and the third organic light-emitting diode is configured to emit blue light.

6. The display apparatus of claim 4, wherein the first organic light-emitting diode is disposed to correspond to the first emission area, the second organic light-emitting diode is disposed to correspond to the second emission area, and the third organic light-emitting diode is disposed to correspond to the third emission area.

7. The display apparatus of claim 1, further comprising a second metal pattern disposed under the first metal pattern.

8. The display apparatus of claim 7, further comprising an insulating layer disposed between the first metal pattern and the second metal pattern.

9. The display apparatus of claim 8, wherein the first metal pattern and the second metal pattern are electrically connected to each other through a contact hole.

10. A display apparatus comprising:
a substrate comprising a first emission area, a second emission area, and a third emission area;
a pixel-defining film disposed on the substrate and comprising an opening;
a first metal pattern disposed on the pixel-defining film; and
a light blocking layer covering the first metal pattern and arranged to surround at least a part of each of the first, second, and third emission areas,
wherein the light blocking layer extending in a first direction and surrounding the second emission area comprises a first edge protruding to an edge of the second emission area and a second edge extending in the first direction and disposed farther from the edge of the second emission area than the first edge, and
wherein a ratio of a length of the first emission area in a second direction intersecting the first direction, a length of the second emission area in the second direction, and a length of the third emission area in the second direction is same as a ratio of a length from an end of the light blocking layer extending in the first direction and surrounding the first emission area to an end of the adjacent first metal pattern, a length from an end of the first edge of the light blocking layer surrounding the second emission area to an end of the adjacent first metal pattern, and a length from an end of the light blocking layer extending in the first direction and surrounding the third emission area to an end of the adjacent first metal pattern.

11. The display apparatus of claim 10, wherein the length from the end of the first edge of the light blocking layer surrounding the second emission area to the end of the adjacent first metal pattern and a length from an end of the second edge of the light blocking layer to an end of the adjacent first metal pattern are different from each other.

12. The display apparatus of claim 10, wherein the light blocking layer extending in the first direction and surrounding the third emission area comprises a third edge protruding to an edge of the third emission area and a fourth edge extending in the first direction and disposed farther from the edge of the third emission area than the third edge.

13. The display apparatus of claim 12, wherein a length from an end of the third edge of the light blocking layer surrounding the third emission area to the adjacent first metal pattern and a length from an end of the fourth edge of the light blocking layer to the adjacent first metal pattern are different from each other.

14. The display apparatus of claim 13, wherein a ratio of the length of the first emission area in the second direction, the length of the second emission area in the second direction, and the length of the third emission area in the second direction is same as a ratio of the length from the end of the light blocking layer extending in the first direction and surrounding the first emission area to the end of the adjacent first metal pattern, the length from the end of the first edge of the light blocking layer surrounding the second emission area to the end of the adjacent first metal pattern, and the length from the end of the third edge of the light blocking layer surrounding the third emission area to an end of the adjacent first metal pattern.

15. The display apparatus of claim 10, wherein the first edge of the light blocking layer surrounding the second emission area comprises a 1-1 edge and a 1-2 edge.

16. The display apparatus of claim 15, wherein a length from an end of the 1-1 edge of the light blocking layer surrounding the second emission area to the adjacent first metal pattern and a length from an end of the 1-2 edge of the light blocking layer to the adjacent first metal pattern are different from each other.

17. The display apparatus of claim 16, wherein a ratio of the length of the first emission area in the second direction, the length of the second emission area in the second direction, and the length of the third emission area in the second direction is same as a ratio of the length from the end of the light blocking layer extending in the first direction and surrounding the first emission area to the end of the adjacent first metal pattern, the length from the end of the 1-1 edge of the light blocking layer surrounding the second emission area to an end of the adjacent first metal pattern, and the length from the end of the light blocking layer extending in the first direction and surrounding the third emission area to the end of the adjacent first metal pattern.

18. The display apparatus of claim 16, wherein the light blocking layer extending in the first direction and surrounding the third emission area comprises a third edge protruding to an edge of the third emission area and a fourth edge extending in the first direction and disposed farther from the edge of the third emission area than the third edge.

19. The display apparatus of claim 18, wherein a length from an end of the third edge of the light blocking layer surrounding the third emission area to the adjacent first metal pattern and a length from an end of the fourth edge of the light blocking layer to the adjacent first metal pattern are different from each other.

20. The display apparatus of claim 19, wherein a ratio of the length of the first emission area in the second direction, the length of the second emission area in the second direction, and the length of the third emission area in the second direction is same as a ratio of the length from the end of the light blocking layer extending in the first direction and surrounding the first emission area to the end of the adjacent first metal pattern, the length from the end of the 1-1 edge of the light blocking layer surrounding the second emission area to an end of the adjacent first metal pattern, and the length from the end of the third edge of the light blocking layer surrounding the third emission area to an end of the adjacent first metal pattern.
